(19) United States
(12) Patent Application Publication
(10) Pub. No.: US 2024/0379900 A1
(43) Pub. Date: Nov. 14, 2024

(54) MICRO LIGHT-EMITTING DEVICE

(71) Applicant: XIAMEN SAN'AN OPTOELECTRONICS CO., LTD., Xiamen (CN)

(72) Inventors: Chaohsu LAI, Xiamen (CN); Chung-ying CHANG, Xiamen (CN); Hsin-yu LIU, Xiamen (CN)

(21) Appl. No.: 18/781,175

(22) Filed: Jul. 23, 2024

Related U.S. Application Data
(63) Continuation-in-part of application No. PCT/CN2023/072902, filed on Jan. 18, 2023.

(30) Foreign Application Priority Data
Jan. 25, 2022 (CN) 202210090499.4

(51) Int. Cl. H01L 33/06; H01L 33/32

(52) U.S. Cl. CPC H01L 33/06; H01L 33/325

(57) ABSTRACT

A micro LED includes an n-type semiconductor layer, a p-type semiconductor layer, a transition structure, an active structure and a hole injection layer. The transition structure includes first to third transition units. The active structure includes an M number of quantum well structures. Each of the M number of quantum well structures includes a barrier layer and a well layer. The third transition unit includes a Q number of layer units each including a barrier layer and a well layer. In each of the Q number of layer units, the barrier layer has an Al concentration that is 1.2 to 3 times an Al concentration of the barrier layer of each 10 of the M number of quantum well structures. The hole injection layer has an Al concentration that is not greater than the Al concentration of the barrier layer of each of the M number of quantum well structures.

### CROSS-REFERENCE TO RELATED APPLICATION

This application is a continuation-in-part (CIP) of International Application No. PCT/CN2023/072902, filed on Jan. 18, 2023, which claims priority to Chinese Invention patent application Ser. No. 20/221,0090499.4, filed on Jan. 25, 2022. The aforesaid applications are incorporated by reference herein in their entirety.

### FIELD

The disclosure relates to a semiconductor device, and more particularly to a micro light-emitting device.

### BACKGROUND

A light-emitting device (LED) is a semiconductor electronic component that emits light. As a new solid-state lighting source that is environmentally friendly with high efficiency, the LED is being rapidly and widely used as traffic signals, automotive interior and exterior lights, urban landscape lighting, cell phone backlight sources, etc.

A micro LED is high-density arrays of tiny-sized LEDs integrated on a single chip, i.e., minimization and arrayization of the LEDs. Micro LED pixels are required to be micron-sized. The micro LED has advantages of an inorganic LED, such as high efficiency, high luminance, high reliability, fast response time, etc., has a characteristic of self-lighting without backlighting, and further has benefits such as energy-saving, a simple mechanism, a small size, a thin thickness, etc. However, how to maintain internal quantum efficiency (IQE) of the micro LED in a high level has become a technical problem that needs to be overcome for the industry.

### SUMMARY

Therefore, an object of the disclosure is to provide a micro light-emitting device (LED) that can alleviate at least one of the drawbacks of the prior art.

According to the disclosure, the micro LED includes an n-type semiconductor layer, a p-type semiconductor layer, a transition structure, an active structure and a hole injection layer. The transition structure includes a first transition unit, a second transition unit and a third transition unit that are sequentially disposed on the n-type semiconductor layer along a direction from the n-type semiconductor layer to the p-type semiconductor layer. The active structure is disposed between the transition structure and the p-type semiconductor layer, and includes an M number of quantum well structures. Each of the M number of quantum well structures includes a barrier layer and a well layer. The hole injection layer is disposed between and connected to the active structure and the p-type semiconductor layer. In each of the M number of quantum well structures, the barrier layer has a composition represented by Alₓ₁In_{y1}Ga_{1-x1-y1}N and the well layer has a composition represented by Alₓ₂In_{y2}Ga_{1-x2-y2}N, where 0≤x₂<x₁≤1 and 0≤y₁<y₂≤1. M is not greater than five, and the well layer has a thickness not greater than 25 Å. The third transition unit includes a Q number of layer units each including a barrier layer and a well layer. In each of the Q number of layer units, the barrier layer has a composition represented by Alₘ₁Inₙ₁Ga₁₋ₘ₁₋ₙ₁N and the well layer has a composition represented by Alₘ₂Inₙ₂Ga₁₋ₘ₂₋ₙ₂N, where 0≤m₂≤m₁≤1 and 0≤n₁≤n₂≤1. Q ranges from 5 to 15, and the barrier layer has an Al concentration that is 1.2 to 3 times an Al concentration of the barrier layer of each of the M number of quantum well structures. The hole injection layer has an Al concentration that is not greater than the Al concentration of the barrier layer of each of the M number of quantum well structures.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic side view of a first embodiment of a micro LED according to the disclosure, illustrating an epitaxial structure disposed on a substrate of the micro LED.

FIG. 2 is a schematic side view illustrating a transition structure of the first embodiment.

FIG. 3 is a schematic top view of the first embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

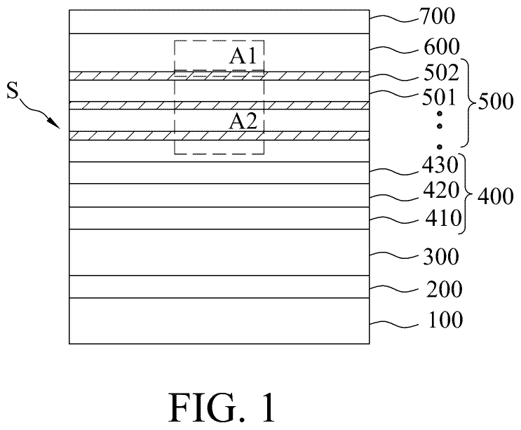

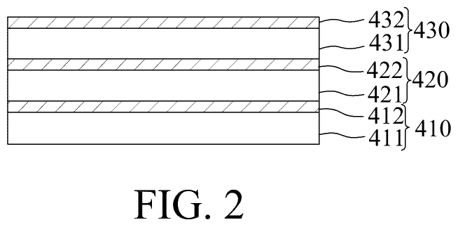

Referring to FIGS. 1 and 2, a first embodiment of a micro light-emitting device (LED) according to the disclosure includes an n-type semiconductor layer 300, a p-type semiconductor layer 700, a transition structure 400, an active structure 500 and a hole injection layer 600. In the industry, a size of a micro LED is currently defined as an LED with an area not greater than 5000 μm², such as an LED having a rectangular cross-section that has a side with a length not greater than 50 μm. In this embodiment, in a top view of the micro LED, an area thereof is not greater than 5000 μm²; the micro LED is made of a GaN-based semiconductor material, the n-type semiconductor layer 300 is a GaN-based semiconductor layer doped with silicon, and the p-type semiconductor layer 700 is a GaN-based semiconductor layer doped with magnesium. The n-type semiconductor layer 300 and the p-type semiconductor layer 700 are formed with a p-n junction therebetween.

In a manufacturing process of the micro LED of the disclosure, a substrate 100 is first provided. The substrate 100 is made of a silicon material or a sapphire material, and in the first embodiment, the substrate 100 is a sapphire substrate. The sapphire substrate 100 may be a patterned sapphire substrate (PSS), a nano-patterned sapphire substrate (NPSS) or a flat substrate. An epitaxial structure of the micro LED is disposed on the sapphire substrate 100; specifically, a buffer layer 120, the n-type semiconductor layer 300, the transition structure 400, the active structure 500, the hole injection layer 600 and the p-type semiconductor layer 700 are sequentially disposed on the sapphire substrate 100. A material of the buffer layer 200 is AlN or AlGaN. The transition structure 400 includes a first transition unit 410, a second transition unit 420 and a third transition unit 430 that are sequentially disposed on the n-type semiconductor layer 300 along a direction from the n-type semiconductor layer 300 to the p-type semiconductor layer 700, serves to decelerate electrons that is in the n-type semiconductor layer 300 flowing to the active structure 500, and controls a gradual increase of an In concentration therein to reduce the lattice mismatch.

A growth temperature for forming the first transition unit 410 is lower than a growth temperature for forming the n-type semiconductor layer 300, and the first transition unit 410 has a carbon concentration that is greater than a carbon concentration of the n-type semiconductor layer 300.

The second transition unit 420 includes an F number of layer units each including a barrier layer 421 and a well layer 422, and in each of the F number of layer units of the second transition unit 420, the barrier layer 421 has a composition represented by Alₑ₁In_{f1}Ga_{1-e1-f1}N and the well layer 422 has a composition represented by Alₑ₂In_{f2}Ga_{1-e2-f2}N, where 0≤e₂≤e₁≤1 and 0≤f₁≤f₂≤1.

The third transition unit 430 includes a Q number of layer units each including a barrier layer 431 and a well layer 432, and in each of the Q number of layer units, the barrier layer 431 has a composition represented by Alₘ₁Inₙ₁Ga₁₋ₘ₁₋ₙ₁N, the well layer 432 has a composition represented by Alₘ₂Inₙ₂Ga₁₋ₘ₂₋ₙ₂N, where 0≤m₂≤m₁≤1 and 0≤n₁≤n₂≤1, , and Q ranges from 5 to 15. With an enough number of layer units, the third transition unit 430 has an effect of deceleration of electrons. When the electrons provided by the n-type semiconductor layer 300 pass through the third transition unit 430 and enter into the quantum well structures of the active structure 500, if Q is less than 5, it is too easy for the electrons to pass through the active structure 500, and an electron concertation of the active structure 500 is too low; if Q is greater than 15, an amount of the electrons that enter into the quantum well structures of the active structure 500 reduces. In both situations, it is not beneficial to improvement of internal quantum efficiency (IQE) of the micro LED.

The active structure 500 is disposed between the transition structure 400 and the p-type semiconductor layer 700 (specifically, the active structure 500 is disposed on the third transition unit 430), and includes an M number of quantum well structures. Each of the M number of quantum well structures includes a barrier layer 501 and a well layer 502. The barrier layer 431 has an Al concentration that is 1.2 to 3 times an Al concentration of the barrier layer 501 of each of the M number of quantum well structures.

The hole injection layer 600 is disposed on the active structure 500 and disposed between and connected to the active structure 500 and the p-type semiconductor layer 700. The hole injection layer 600 facilitates holes in the p-type semiconductor layer 700 to flow into the M number of quantum well structures of the active structure 500. Specifically, in the micro LED, the holes in the p-type semiconductor layer 700 and the electrons in the n-type semiconductor layer 300 converge toward the active structure 500 and recombine therein to emit light.

In the first embodiment, when the epitaxial structure of the micro LED is designed to have a reduced thickness (for example, M is reduced), in each of the M number of quantum well structures, the barrier layer 501 has a composition represented by Alₓ₁ln_{y1}Ga_{1-x1-y1}N and the well layer 502 has a composition represented by Alₓ₂In_{y2}Ga_{1-x2-y2}N, where 0≤x₂≤x₁≤1 and 0≤y₁≤y₂≤1, M is not greater than five, and the well layer 502 has a thickness not greater than 25 Å. The micro LED is adapted to emit light having a wavelength shorter than 600 nm (such as blue light or green light), and 0.15≤y2≤0.3. In some embodiments, in each of the M number of quantum well structures, the barrier layer 501 has a thickness ranging from 80 Å to 150 Å, the well layer 502 has the thickness ranging from 10 Å to 25 Å (in other embodiments, the thickness of the well layer 502 may range from 10 Å to 20 Å), the Al concentration of the barrier layer 501 ranges from 1.5E19/cm³ to 3E19/cm³, and an In concentration of the well layer 502 ranges from 2E20/cm³ to 3.5E20/cm³.

A ratio of an In concentration of the well layer 432 of each of the Q number of layer units of the third transition unit 430 to an In concentration of the first transition unit 410 is a first value (K1), a ratio of the In concentration of the well layer 432 of each of the Q number of layer units of the third transition unit 430 to an In concentration of the well layer 422 of each of the F number of layer units of the second transition unit 420 is a second value (K2), and a ratio of the first value (K1) to the second value (K2) is not smaller than 30. Compared to the In concentration of the well layer 432 of each of the Q number of layer units of the third transition unit 430, the In concentration of the well layer 422 of each of the F number of layer units of the second transition unit 420 is relatively low, which facilitates adjustment of growth stress of the active structure 500 and adjustment of lattice mismatch between the transition structure 400 and the active structure 500, and thereby reduces growth stress of the active structure 500.

The hole injection layer 600 has a composition represented by Alⱼ₁Inₖ₁Ga₁₋ⱼ₁₋ₖ₁N, where 0≤j₁≤0.05 and 0≤k₁≤0.05. The hole injection layer 600 has a first portion (i.e., an upper portion in this embodiment) adjacent to the p-type semiconductor layer 700 and a second portion (i.e., a bottom portion in this embodiment) adjacent to the active structure 500. The holes in the p-type semiconductor layer 700 move to the hole injection layer 600. The hole injection layer 600 has an Al concentration that is not greater than (in this embodiment, that is lower than) the Al concentration of the barrier layer 501 of each of the M number of quantum well structures. Compared to a LED, a conventional micro LED has a size not greater than 50 μm, which leads to rising of non-radiative recombination on a sidewall of the conventional micro LED and increasing of thermal effect, such that luminous efficiency of the conventional micro LED is adversely affected. Referring to FIG. 1, in this embodiment, by virtue of reducing the Al concentration of the hole injection layer 600, a two-dimensional electron gas (2DEG) on a cross-section of the epitaxial structure reduces, a hole concentration of a first center portion (A1) of the hole injection layer 600 increases, and the holes are prevented from moving to a sidewall (S) of the epitaxial structure (i.e., an ineffective lighting area), such that the holes enter a second center portion (A2) of the active structure 500, increasing utilization of the electric currents.

The hole injection layer 600 is connected to the well layer 502 of one of the M number of quantum well structures, and has a thickness ranging from 200 Å to 2000 Å. By virtue of the sufficient thickness of the hole injection layer 600, the holes stay in the second center portion (A2) when entering into the active structure 500. When the thickness of the hole injection layer 600 is smaller than 200 Å, efficiency of blocking the electrons becomes worse.

An Al concentration of the first portion of the hole injection layer 600 is lower than an Al concentration of the second portion of the hole injection layer 600, which is beneficial to the holes entering into the quantum well structures of the active structure 500.

The barrier layer 421 of each of the F number of layer units of the second transition unit 420 has an Al concentration that is one-tenth to one-fifth of the Al concentration of the barrier layer 431 of each of the Q number of layer units of the third transition unit 430. In practice, due to the diffusion of components or errors in measurement, the Al concentration of the barrier layer 421 of each of the F number of layer units of the second transition unit 420 may be smaller than one-tenth of the Al concentration of the barrier layer 431 of each of the Q number of layer units of the third transition unit 430. In each of the Q number of layer units of the third transition unit 430, the Al concentration of the barrier layer 431 ranges from 2E18/cm³ to 4E19/cm³, and the In concentration of the well layer 432 ranges from 1E20/cm³ to 3E20/cm³. A material of the barrier layer 431 of each of the Q number of layer units of the third transition unit 430 matches a material of the active structure 500, decreasing an effect of stress of the third transition unit 430 to the active structure 500. The In concentration of the well layer 422 of each of the F number of layer units of the second transition unit 420 ranges from 4E19/cm³ to 8E19/cm³.

In each of the Q number of layer units of the third transition unit 430, the barrier layer 431 has a thickness that is 3 times to 8 times a thickness of the well layer 432. In each of the F number of layer units of the second transition unit 420, the barrier layer 421 has a thickness that is 4 times to 25 times a thickness of the well layer 422. When the thickness of the barrier layer 421 is less than 4 times the thickness of the well layer 422, efficient V-defects are hard to be induced and antistatic capacity of the micro LED may be insufficient. When the thickness of the barrier layer 421 is greater than 25 times the thickness of the well layer 422, the V-defects are so large that crystal quality of the epitaxial structure decreases.

The transition structure 400 has a thickness ranging from 2000 Å to 5000 Å; specifically, the first transition unit 410 has a thickness of 2000 Å±50%, the second transition unit 420 has a thickness of 600 Å±50%, and the third transition unit 430 has a thickness of 900 Å±50%. In some embodiments, Q ranges from 8 to 10, and each of the Q number of layer units of the third transition unit 430 has a thickness ranging from 100 Å to 150 Å; F ranges from 2 to 5, and each of the F number of layer units of the second transition unit 420 has a thickness ranging from 150 Å to 200 Å.

The thickness of the first transition unit 410 is 1.2 times to 2 times a thickness of the active structure 500. In the first transition unit 410, an Al concentration is not greater than 1E18/cm³, and an In concentration is not greater than 8E18/cm³. That is, Al accounts for at least smaller than 1% of a material of the first transition unit 410. When the Al concentration of the first transition unit 410 is too high, luminance of the micro LED reduces and a forward voltage with which the micro LED is adapted to be used rises.

The first transition unit 410 has the In concentration that is smaller than the In concentration of the second well layer 422 of each of the F number of layer units of the second transition unit 420. The In concentration of the first transition unit 410 is not greater than one-tenth of the Al concentration of the well layer 422 of each of the F number of layer units of the second transition unit 420.

In some embodiments, due to the diffusion of components or errors in measurement, the In concentration of the first transition unit 410 may be one-tenth to one-fifth of the In concentration of the well layer 422 of each of the F number of layer units of the second transition unit 420. In the disclosure, the first transition unit 410 is formed at a low temperature with relatively poor growth quality, which induces V-defects, further improves efficiency of the holes entering into the active structure 500, and takes releasing of the growth stress into account. The growth temperature for forming the first transition unit 410 is lower than the growth temperature for forming the n-type semiconductor layer 300, and the first transition unit 410 has the carbon concentration that is greater than the carbon concentration of the n-type semiconductor layer 300.

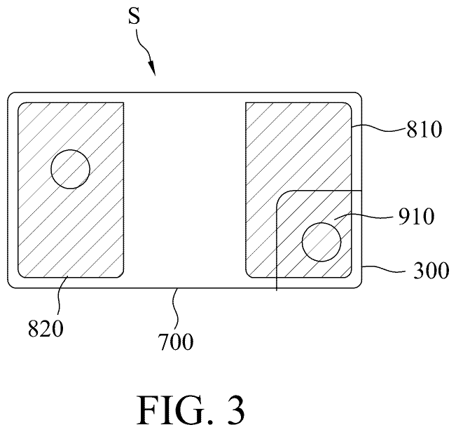

Referring to FIG. 3, in the manufacturing process of the micro LED, an n-type electrode 810 and a p-type electrode 820 are disposed to be electrically connected to the n-type semiconductor layer 300 and the p-type semiconductor layer 700, respectively, through dielectric holes. In this embodiment, the micro LED is adapted to be used with a current density not greater than 1 ampere/cm², but the disclosure is not limited hereto. In some embodiments, the sapphire substrate 100 may be removed as needed by etching or peeling off.

In a second embodiment of the disclosure, different from the first embodiment, the active structure 500 includes carbon, and has a carbon concentration that is lower than 1E16/cm³, thereby reducing non-radiative recombination in the active structure 500; in addition, in a design of ultrathin quantum well structures, reduction of the carbon concentration of the active structure 500 can effectively reduce non-radiative recombination in the quantum well structures. For example, in each of the M number of quantum well structures, the barrier layer 501 has the thickness ranging from 80 Å to 150 Å, and the well layer 502 has the thickness ranging from 10 Å to 20 Å; in addition, in the active structure 500, the barrier layers 501 and the well layers 502 are arranged in a manner where one of the barrier layers 501 and one of the well layers 502 are grouped into one of the M number of quantum well structures, and M is not greater than 5.

Specifically, the n-type semiconductor layer 300 providing the electrons is disposed on the buffer layer 200, and the first transition unit 410, the second transition unit 420 and the third transition unit 430 are sequentially disposed on the n-type semiconductor layer 300 along the direction. The transition structure 400 serves to decelerate electrons that is in the n-type semiconductor layer 300 flowing to the active structure 500, and controls a gradual increase of an In concentration therein to reduce the lattice mismatch.

In a third embodiment of the disclosure, it differs from the first embodiment in that the Al concentration of the hole injection layer 600 is not greater than 1E19/cm³, such that the 2DEG on the cross-section of the epitaxial structure reduces, the hole concentration of the first center portion (A1) of the hole injection layer 600 increases, and the holes are prevented from moving to the sidewall (S) of the epitaxial structure; especially, the holes are prevented from moving to sidewalls of the hole injection layer 600 and the active structure 500.

In the disclosure, a conventional electron blocking layer that includes Al and that is disposed between the active structure 500 and the p-type semiconductor layer 700 is replaced by the hole injection layer 600 that has a relatively low Al concentration, such that the holes will not be blocked by the electron blocking layer, and the hole injection efficiency from the p side (i.e., the p-type semiconductor layer 700) increases; besides, since the active structure 500 has a reduced thickness and the electron blocking layer is replaced, an electron concentration in the active structure 500 is reduced.

For a matching design, the transition structure 400 is disposed between the active structure 500 and the n-type semiconductor layer 300. By virtue of a superlattice structure and the Al concentration of the transition structure 400, a speed at which the electrons entering into the active structure 500 is reduced, such that more electrons stay in the active structure 500, thereby improving the hole and electron concentrations of the active structure 500 to increase efficiency of recombination of the holes and the electrons.

In a fourth embodiment of the disclosure, different from the third embodiment, the hole injection layer 600 that is disposed between the active structure 500 and the p-type semiconductor layer 700 has the Al concentration not greater than 5E18/cm⁵. In practice, in the manufacturing process of the micro LED, it is possible to not introduce an aluminum source for growing the hole injection layer 600 so that the hole injection layer 600 has the Al concentration not greater than 1E18/cm³.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A micro light-emitting device (LED) comprising:
an n-type semiconductor layer;
a p-type semiconductor layer;
a transition structure including a first transition unit, a second transition unit and a third transition unit that are sequentially disposed on said n-type semiconductor layer along a direction from said n-type semiconductor layer to said p-type semiconductor layer;
an active structure disposed between said transition structure and said p-type semiconductor layer, and including an M number of quantum well structures, each of the M number of quantum well structures including a barrier layer and a well layer; and
a hole injection layer disposed between and connected to said active structure and said p-type semiconductor layer;
wherein
in each of the M number of quantum well structures, said barrier layer has a composition represented by Alₓ₁In_{y1}Ga_{1-x1-y1}N and said well layer has a composition represented by Alₓ₂In_{y2}Ga_{1-x2-y2}N, where 0≤x₂<x₁≤1 and 0≤y₁<y₂≤1, M is not greater than five, and said well layer has a thickness not greater than 25 Å,
said third transition unit includes a Q number of layer units each including a barrier layer and a well layer, and in each of the Q number of layer units, said barrier layer has a composition represented by Alₘ₁Inₙ₁Ga₁₋ₘ₁₋ₙ₁N and said well layer has a composition represented by Alₘ₂Inₙ₂Ga₁₋ₘ₂₋ₙ₂N, where 0≤m₂≤m₁≤1 and 0≤n₁≤n₂≤1, Q ranges from 5 to 15, and said barrier layer has an Al concentration that is 1.2 to 3 times an Al concentration of said barrier layer of each of the M number of quantum well structures, and said hole injection layer has an Al concentration that is not greater than said Al concentration of said barrier layer of each of the M number of quantum well structures.

2. The micro LED as claimed in claim 1, wherein
said second transition unit includes an F number of layer units each including a barrier layer and a well layer, and in each of the F number of layer units of said second transition unit, said barrier layer has a composition represented by Alₑ₁In_{f1}Ga_{1-e1-f1}N and said well layer has a composition represented by Alₑ₂In_{f2}Ga_{1-e2-f2}N, where 0≤e₂≤e₁≤1 and 0≤f₁≤f₂≤1, and
a ratio of an In concentration of said well layer of each of the Q number of layer units of said third transition unit to an In concentration of said first transition unit is a first value, a ratio of said In concentration of said well layer of each of the Q number of layer units of said third transition unit to an In concentration of said well layer of each of the F number of layer units of said second transition unit is a second value, and a ratio of said first value to said second value is not smaller than 30.

3. The micro LED as claimed in claim 2, wherein said barrier layer of each of the F number of layer units of said second transition unit has an Al concentration that is one-tenth to one-fifth of said Al concentration of said barrier layer of each of the Q number of layer units of said third transition unit, or that is smaller than one-tenth of said Al concentration of said barrier layer of each of the Q number of layer units of said third transition unit.

4. The micro LED as claimed in claim 2, wherein said In concentration of said well layer of each of the F number of layer units of said second transition unit ranges from 4E19/cm³ to 8E19/cm³.

5. The micro LED as claimed in claim 1, wherein in each of the Q number of layer units of said third transition unit, said Al concentration of said barrier layer ranges from 2E18/cm³ to 4E19/cm³, and an In concentration of said well layer ranges from 1E20/cm³ to 3E20/cm³.

6. The micro LED as claimed in claim 1, wherein
said transition structure has a thickness ranging from 2000 Å to 5000 Å,
said first transition unit has a thickness of 2000 Å±50%,
said second transition unit has a thickness of 600 Å±50%, and
said third transition unit has a thickness of 900 Å±50%.

7. The micro LED as claimed in claim 1, wherein
Q ranges from 8 to 10, and each of the Q number of layer units of said third transition unit has a thickness ranging from 100 Å to 150 Å, and
said second transition unit includes an F number of layer units each including a barrier layer and a well layer, F ranges from 2 to 5, and each of the F number of layer units of said second transition unit has a thickness ranging from 150 Å to 200 Å.

8. The micro LED as claimed in claim 1, wherein said hole injection layer has a composition represented by Alⱼ₁Inₖ₁Ga₁₋ⱼ₁₋ₖ₁N, where 0≤j₁≤0.05 and 0≤k₁≤0.05.

9. The micro LED as claimed in claim 1, wherein said hole injection layer is connected to said well layer of one of the M number of quantum well structures, and said hole injection layer has a thickness ranging from 200 Å to 2000 Å.

10. The micro LED as claimed in claim 1, wherein said micro LED is adapted to be used with a current density not greater than 1 ampere/cm².

11. The micro LED as claimed in claim 1, wherein said micro LED is adapted to emit light having a wavelength shorter than 600 nm, and 0.15≤y2≤0.3.

12. The micro LED as claimed in claim 1, wherein in each of the Q number of layer units of said third transition unit, said barrier layer has a thickness that is 3 times to 8 times a thickness of said well layer, and
said second transition unit includes an F number of layer units each including a barrier layer and a well layer, and in each of the F number of layer units of said second transition unit, said barrier layer has a thickness that is 4 times to 25 times a thickness of said well layer.

13. The micro LED as claimed in claim 1, wherein in each of the M number of quantum well structures, said barrier layer has a thickness ranging from 80 Å to 150 Å, said well layer has the thickness ranging from 10 Å to 25 Å, said Al concentration of said barrier layer ranges from 1.5E19/cm³ to 3E19/cm³, and an In concentration of said well layer ranges from 2E20/cm³ to 3.5E20/cm³.

14. The micro LED as claimed in claim 1, wherein said micro LED is made of a GaN-based semiconductor material, said n-type semiconductor layer is a GaN-based semiconductor layer doped with silicon, and said p-type semiconductor layer is a GaN-based semiconductor layer doped with magnesium.

15. The micro LED as claimed in claim 1, wherein said active structure includes carbon, and a carbon concentration of said active structure is lower than 1E16/cm³.

16. The micro LED as claimed in claim 1, wherein said hole injection layer has a first portion adjacent to said p-type semiconductor layer and a second portion adjacent to said active structure, an Al concentration of said first portion being lower than an Al concentration of said second portion.

17. The micro LED as claimed in claim 1, wherein said Al concentration of said hole injection layer is not greater than 1E19/cm³.

18. The micro LED as claimed in claim 1, wherein, in said first transition unit, an Al concentration is not greater than 1E18/cm³, and an In concentration is not greater than 8E18/cm³.

19. The micro LED as claimed in claim 1, wherein
said second transition unit includes an F number of layer units each including a barrier layer and a well layer, and
said first transition unit has an In concentration that is one-tenth to one-fifth of an In concentration of said well layer of each of the F number of layer units of said second transition unit, or that is smaller than one-tenth of an Al concentration of said well layer of each of the F number of layer units of said second transition unit.

20. The micro LED as claimed in claim 1, wherein a growth temperature for forming said first transition unit is lower than a growth temperature for forming said n-type semiconductor layer, and said first transition unit has a carbon concentration that is greater than a carbon concentration of said n-type semiconductor layer.
